(19) United States
(12) Patent Application Publication
(10) Pub. No.: US 2019/0174649 A1
(43) Pub. Date: Jun. 6, 2019

(54) SUPPORTING ASSEMBLY SUITABLE FOR RACK

(71) Applicants: KING SLIDE WORKS CO., LTD., Kaohsiung City (TW); KING SLIDE TECHNOLOGY CO., LTD., Kaohsiung City (TW)

(72) Inventors: KEN-CHING CHEN, KAOHSIUNG CITY (TW); SHUN-HO YANG, KAOHSIUNG CITY (TW); MEI-ZUO GUO, KAOHSIUNG CITY (TW); CHUN-CHIANG WANG, KAOHSIUNG CITY (TW)

(21) Appl. No.: 15/982,180

(22) Filed: May 17, 2018

(30) Foreign Application Priority Data
Dec. 1, 2017 (TW) 106142462

(51) Int. Cl. H05K 7/14; A47B 88/43

(52) U.S. Cl. CPC H05K 7/1489; H05K 7/1411; A47B 88/43

(57) ABSTRACT

A supporting assembly includes a first bracket, a supporting frame, and a second bracket. The first bracket includes a first end portion and a second end portion. The supporting frame is connected to the first bracket at a position adjacent to the second end portion of the first bracket and has a first supporting section. One of the first bracket and the supporting frame is provided with a second supporting section. The first supporting section and the second supporting section jointly constitute a supporting channel for supporting the second bracket.

### FIELD OF THE INVENTION

The present invention relates to a supporting assembly and more particularly to one for use with a rack.

### BACKGROUND OF THE INVENTION

U.S. Pat. No. 6,230,903 B1 discloses a rack slide mounting system. As shown in FIG. 2 accompanying the specification of the US patent, the system includes a first mounting bracket 27 and a second mounting bracket 47. The first mounting bracket 27 is provided with a plurality of elongated slots 33, and the second mounting bracket 47 is provided with a plurality of elongated slots 53. The plural studs 31 and 51 on a slide mechanism 21 are passed through the elongated slots respectively and are each connected with a nut 29 or 48 so that the total length to which the first mounting bracket 27 and the second mounting bracket 47 extend can be adjusted, allowing the two mounting brackets to carry a chassis through the slide mechanism 21. The disclosure of the US patent is incorporated herein by reference.

The first mounting bracket 27 and the second mounting bracket 47 of the bracket assembly disclosed in the afore-cited patent are two separate components, but this structural configuration does not always meet market demands.

### SUMMARY OF THE INVENTION

One objective of the present invention is to provide a supporting assembly whose two brackets are mounted with respect to each other via a supporting frame.

According to one aspect of the invention, a supporting assembly includes a first bracket, a supporting frame, and a second bracket. The first bracket includes a first end portion and a second end portion. The supporting frame is connected to the first bracket at a position adjacent to the second end portion of the first bracket and has a first supporting section. One of the first bracket and the supporting frame is provided with a second supporting section. The first supporting section and the second supporting section jointly constitute a supporting channel for supporting the second bracket.

Preferably, the second bracket is mounted to the first bracket through the supporting channel, and the first bracket and the second bracket include a first mounting member and a second mounting member respectively, wherein the second mounting member is away from the first mounting member.

Preferably, the first bracket has a first lateral side and a second lateral side. The first lateral side is provided with a carrying portion while the first supporting section is located on the second lateral side.

Preferably, the second supporting section is located on the second lateral side and extends in a second direction.

Preferably, the first bracket has a first feature, and the second bracket has a second feature. The first feature and the second feature do not contact each other when the first bracket and the second bracket are extended to a first length. The first feature and the second feature contact each other when the first bracket and the second bracket are extended to a second length.

Preferably, the first feature is one of a protruding portion and an elastic arm, and the second feature is the other of the protruding portion and the elastic arm.

Preferably, the supporting frame is either integrally formed with the first bracket or a separate component connected to the first bracket.

Preferably, the first bracket has the second supporting section.

Preferably, the first bracket includes a sidewall, and the sidewall has not only the first lateral side and the second lateral side, but also an upper portion and a lower portion. The first supporting section is adjacent to the lower portion while the second supporting section is adjacent to the upper portion.

Preferably, the first supporting section is connected with a first bent section.

Preferably, the second supporting section is connected with a second bent section.

Preferably, the second bracket includes an upper wall, a lower wall, and a sidewall connected between the upper wall and the lower wall, wherein the lower wall and the upper wall correspond in position to the first supporting section and the second supporting section respectively.

Preferably, the supporting frame is a separate component connected to the first bracket and has the second supporting section and an intermediate wall connected between the first supporting section and the second supporting section. It is also preferable that the first supporting section and the second supporting section are connected with a first bent section and a second bent section respectively.

According to another aspect of the invention, a supporting assembly adapted to be mounted on a rack includes a first bracket, a supporting frame, and a second bracket. The first bracket includes a sidewall. The sidewall of the first bracket includes a first end portion and a second end portion, and a first mounting member is arranged adjacent to the first end portion. The sidewall of the first bracket also has a first lateral side and a second lateral side. The supporting frame is connected to the second lateral side and has a first supporting section. The second bracket includes a sidewall and a second mounting member. One of the first bracket and the supporting frame is provided with a second supporting section. The first supporting section and the second supporting section jointly constitute a supporting channel for supporting the sidewall of the second bracket. The first bracket is mounted at a first position on a first side of the rack through the first mounting member, and the second bracket is mounted at a second position on the first side of the rack through the second mounting member.

Preferably, the sidewall of the first bracket has a carrying portion on the first lateral side so that the supporting assembly can carry an external object through the carrying portion.

Preferably, the supporting frame is adjacent to the second end portion of the first bracket and is either integrally formed with the first bracket or a separate component connected to the first bracket.

### BRIEF DESCRIPTION OF THE DRAWINGS

FIG. 1 shows how an object is mounted on a rack through a pair of supporting assemblies according to the first embodiment of the present invention;

FIG. 2 is a perspective view of the supporting assembly according to the first embodiment of the present invention;

FIG. 3 is an exploded perspective view of the supporting assembly according to the first embodiment of the present invention;

FIG. 4 is a sectional view of the supporting assembly according to the first embodiment of the present invention, showing how the supporting assembly supports an object;

FIG. 5 shows the pair of supporting assemblies mounted on a rack and extended to a first length according to the first embodiment of the present invention;

FIG. 6 is an enlarged view of the circled area A in FIG. 5;

FIG. 7 is an enlarged view of the circled area B in FIG. 5;

FIG. 8 shows the pair of supporting assemblies mounted on a rack and extended to a second length according to the first embodiment of the present invention;

FIG. 9 is an enlarged view of the circled area A in FIG. 8;

FIG. 10 is an exploded perspective view of a supporting assembly according to the second embodiment of the invention;

FIG. 11 is an assembled perspective view of the supporting assembly according to the second embodiment of the invention;

FIG. 12 is a sectional view of the supporting assembly according to the second embodiment of the invention;

FIG. 13 is an exploded perspective view of a supporting assembly according to the third embodiment of the invention;

FIG. 14 is an assembled perspective view of the supporting assembly according to the third embodiment of the invention; and

FIG. 15 is a sectional view of the supporting assembly according to the third embodiment of the invention.

### DETAILED DESCRIPTION OF THE INVENTION

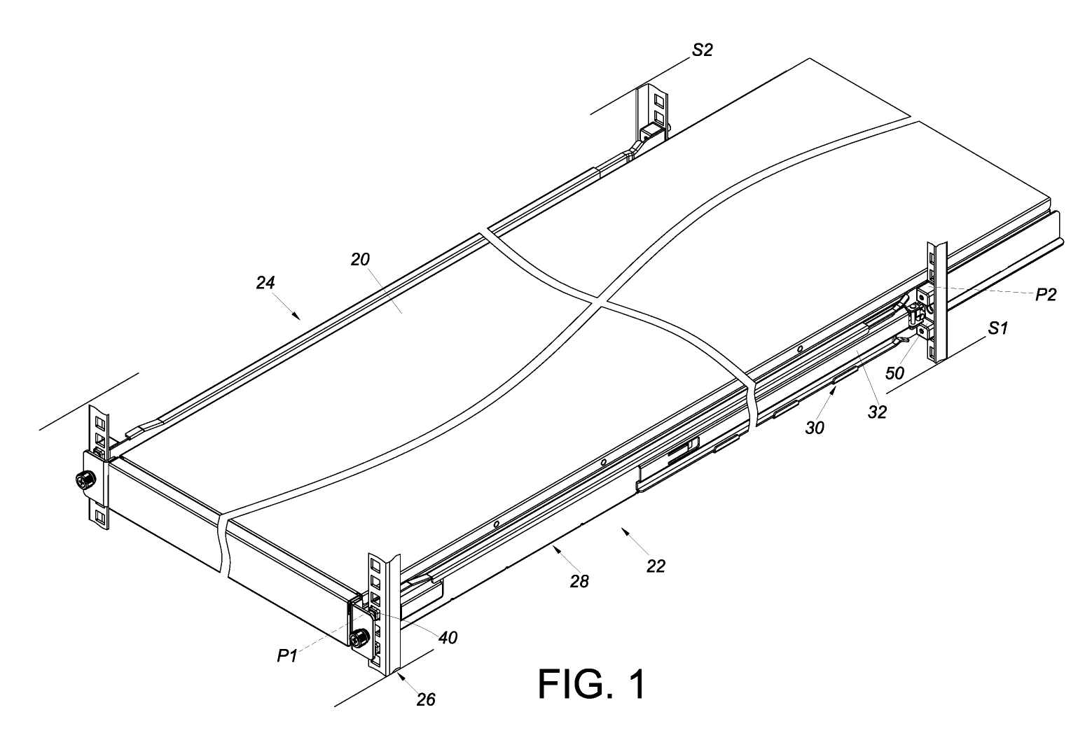

FIG. 1 shows how an object 20, e.g., the chassis of a piece of electronic equipment, is mounted on a rack 26 via a pair of supporting assemblies 22, 24 according to the first embodiment of the present invention. More specifically, the supporting assembly 22 includes a first bracket 28, a supporting frame 30, and a second bracket 32. The first bracket 28 is mounted at a first position P1 on a first side S1 of the rack 26, and the second bracket 32 is mounted at a second position P2 on the first side S1 of the rack 26. The other supporting assembly 24 is mounted on a second side S2 of the rack 26 in a similar manner.

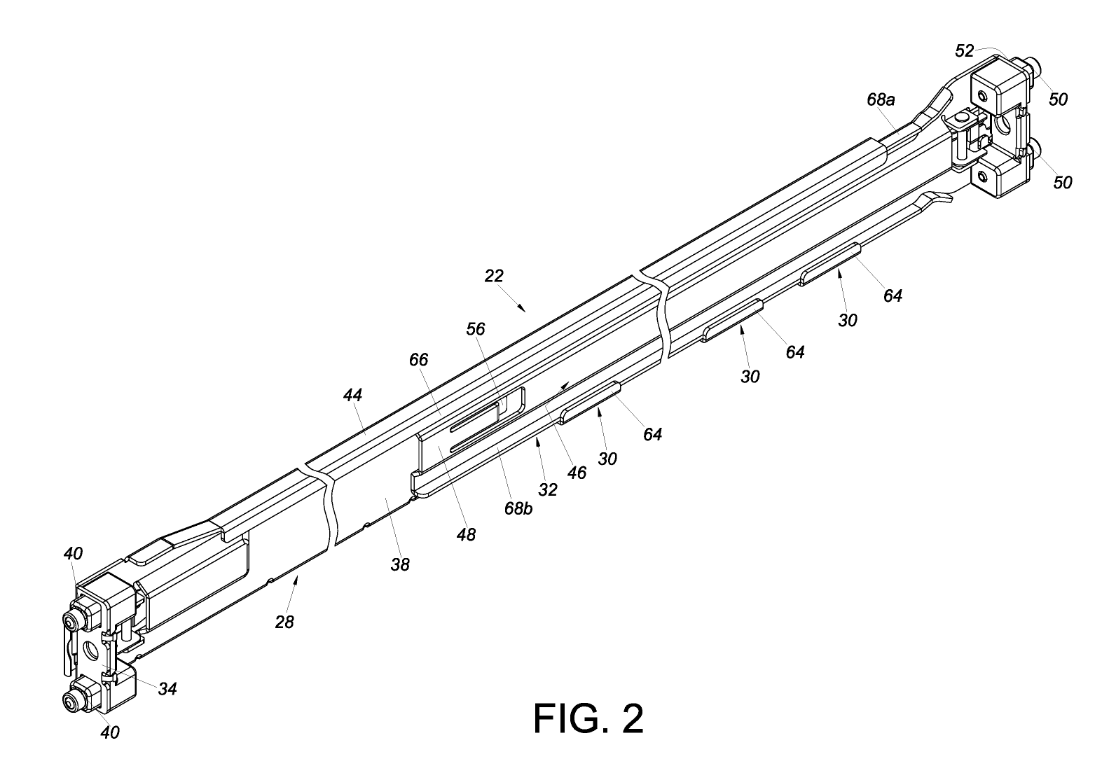

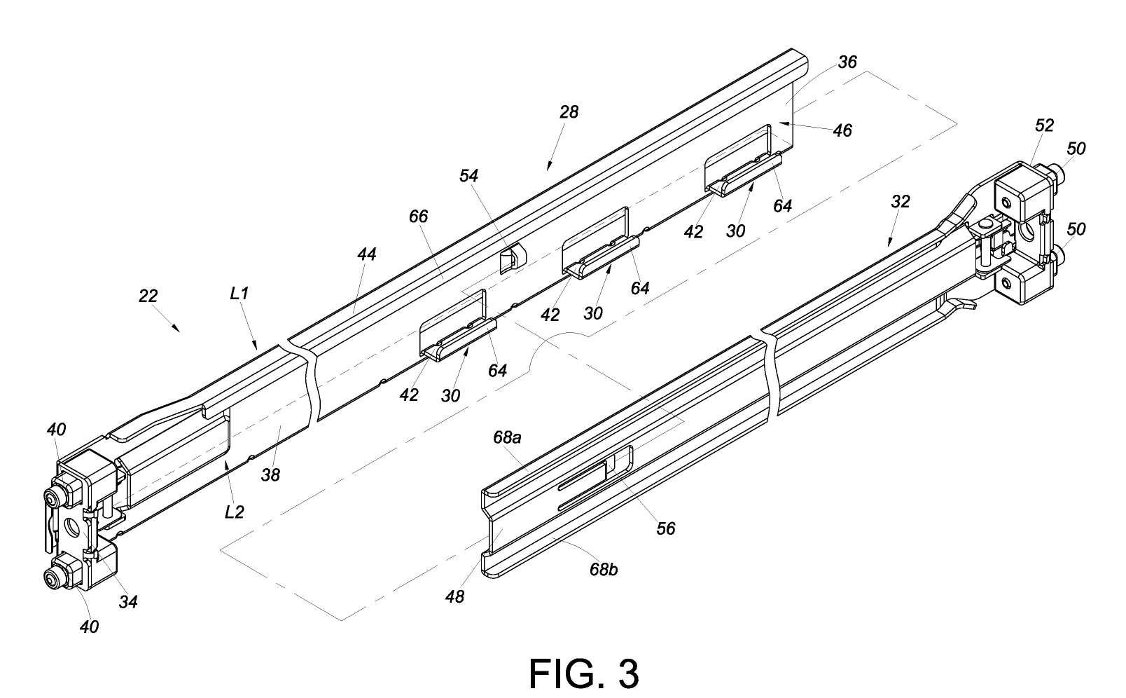

FIG. 2 to FIG. 4 more clearly show the components of the supporting assembly 22 and how the components are arranged in relation to one another. The first bracket 28 of the supporting assembly 22 includes a first end portion 34 and a second end portion 36, such as but not limited to a front end portion and a rear end portion. Preferably, the first bracket 28 includes a sidewall 38 of a predetermined length, and the sidewall 38 includes the first end portion 34 and the second end portion 36, with at least one first mounting member 40 (e.g., two first mounting members 40) arranged adjacent to the first end portion 34. The first bracket 28 is mounted at the first position P1 on the first side S1 of the rack 26 through the first mounting members 40. The sidewall 38 of the first bracket 28 has a first lateral side L1 and a second lateral side L2. For example, the second lateral side L2 is on the opposite side of the first lateral side L1; in other words, the first lateral side L1 and the second lateral side L2 are two opposite sides of the sidewall 38.

In the first embodiment, the supporting frame 30 and the first bracket 28 are integrally formed. The supporting frame 30 is connected to the first bracket 28 at a position adjacent to the second end portion 36. More specifically, the supporting frame 30 is connected to the sidewall 38 of the first bracket 28 and extends from the second lateral side L2. Here, three supporting frames 30 are provided by way of example. In practice, however, only one supporting frame 30 suffices. Each supporting frame 30 has a first supporting section 42. Either the first bracket 28 or the supporting frames 30 are provided with a second supporting section 44. Here, by way of example, it is the first bracket 28 that is provided with the second supporting section 44. The first supporting sections 42 and the second supporting section 44 jointly constitute a supporting channel 46 for supporting the second bracket 32. The second bracket 32 is mounted on the first bracket 28 through the supporting channel 46.

The second bracket 32 includes a sidewall 48 and at least one second mounting member 50 (e.g., two second mounting members 50). The sidewall 48 of the second bracket 32 has a predetermined length and is supported in the supporting channel 46. The second mounting members 50 are arranged adjacent to an end portion 52 of the sidewall 48 of the second bracket 32 and are outside the supporting channel 46. The second mounting members 50 are away from the first mounting members 40. The second bracket 32 is mounted at the second position P2 on the first side S1 of the rack 26 through the second mounting members 50.

Preferably, the sidewall 38 of the first bracket 28 has a first feature 54, and the sidewall 48 of the second bracket 32 has a second feature 56. Here, the first feature 54 is a protruding portion, and the second feature 56 is an elastic arm. In embodiments that are not shown herein, the first feature 54 may be an elastic arm instead while the second feature 56 is a protruding portion; the present invention has no limitation in this regard. That is to say, the first feature 54 is one of a protruding portion and an elastic arm, and the second feature 56 is the other of the protruding portion and the elastic arm. The elastic arm can be moved over the protruding portion elastically in the course in which the second bracket 32 is mounted to the first bracket 28.

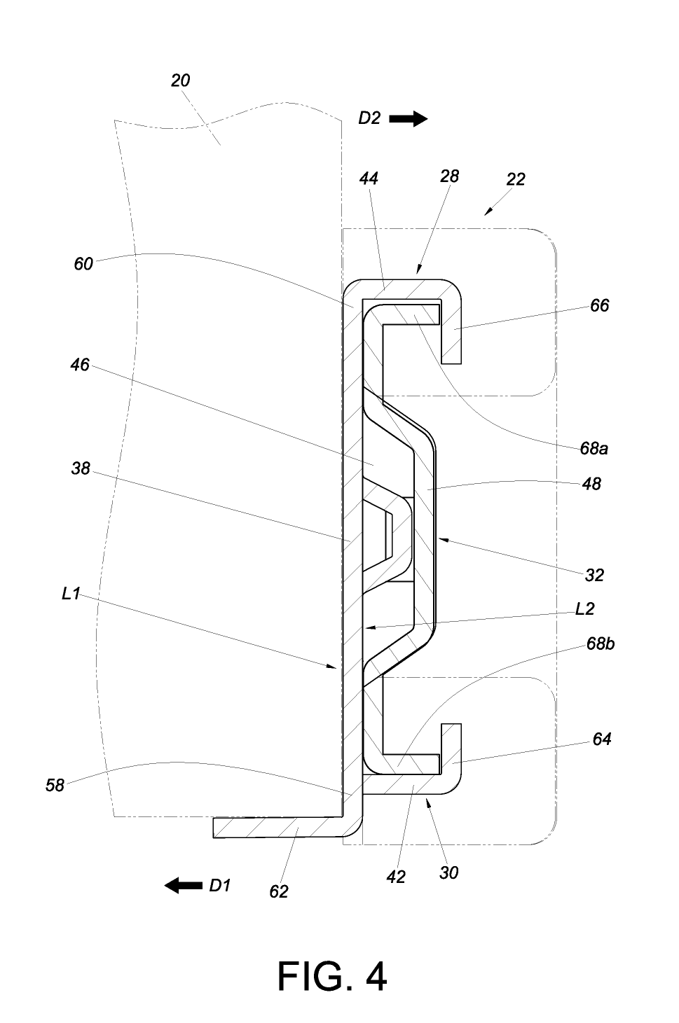

Preferably, as shown in FIG. 4, the first supporting sections 42 and the second supporting section 44 are located on the second lateral side L2 of the sidewall 38 of the first bracket 28, the sidewall 38 of the first bracket 28 has a lower portion 58 and an upper portion 60, the first supporting sections 42 are adjacent to the lower portion 58, and the second supporting section 44 is adjacent to the upper portion 60.

Preferably, as shown in FIG. 4, the first supporting sections 42 extend substantially perpendicularly from the lower portion 58, and the second supporting section 44 extends substantially perpendicularly from the upper portion 60.

Preferably, as shown in FIG. 4, a carrying portion 62 is arranged on the first lateral side L1 of the sidewall 38 of the first bracket 28, is substantially adjacent to the lower portion 58, and extends in a first direction D1. The carrying portion 62 is configured to carry a bottom portion of the object 20 in such a way that a lateral side of the object 20 can be pressed against and thereby supported by the first lateral side L1 of the sidewall 38 of the first bracket 28. The first supporting sections 42 and the second supporting section 44 extend in a second direction D2 that is different from the first direction D1.

Preferably, as shown in FIG. 4, each first supporting section 42 is connected with a first bent section 64, and the second supporting section 44 is connected with a second bent section 66. Here, by way of example, each first bent section 64 is substantially perpendicularly connected to the corresponding first supporting section 42 and extends toward the supporting channel 46, and the second bent section 66 is substantially perpendicularly connected to the second supporting section 44 and extends toward the supporting channel 46.

Preferably, as shown in FIG. 4, the second bracket 32 includes an upper wall 68a and a lower wall 68b, the sidewall 48 is connected between the upper wall 68a and the lower wall 68b, the lower wall 68b corresponds in position to the first supporting sections 42, and the upper wall 68a corresponds in position to the second supporting section 44.

Preferably, as shown in FIG. 4, the first bent sections 64 and the second bent section 66 help keep the second bracket 32 in the supporting channel 46.

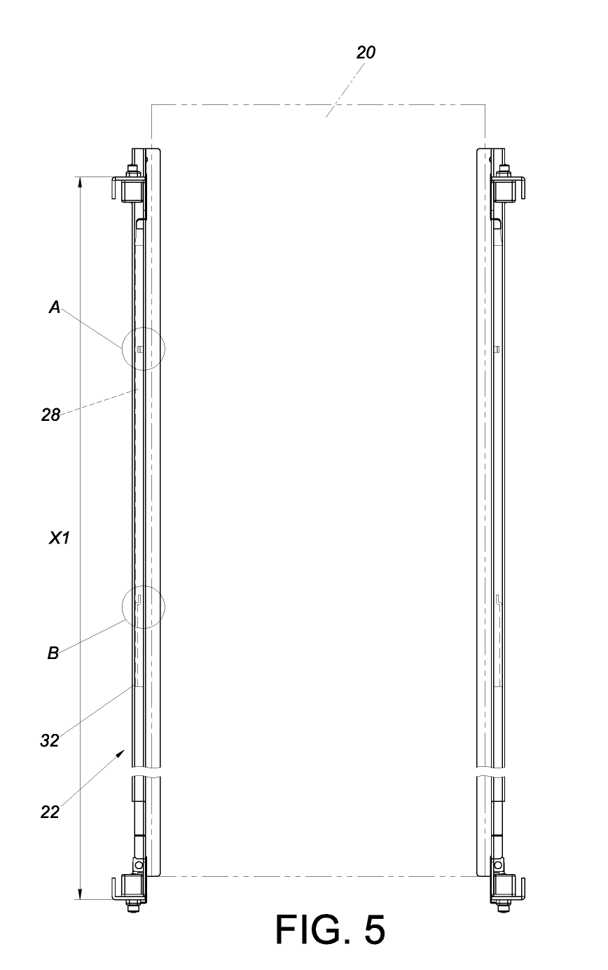

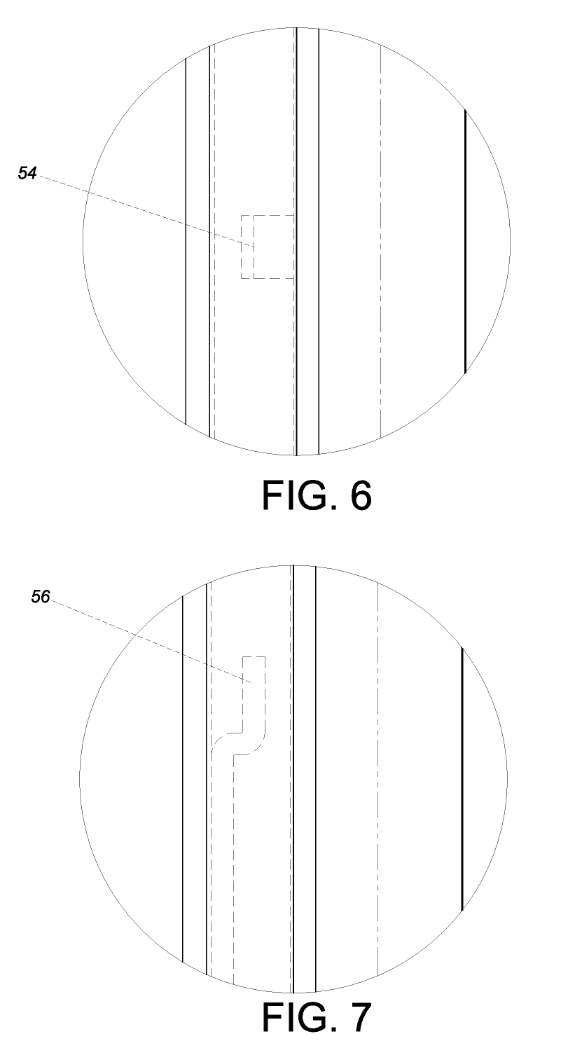

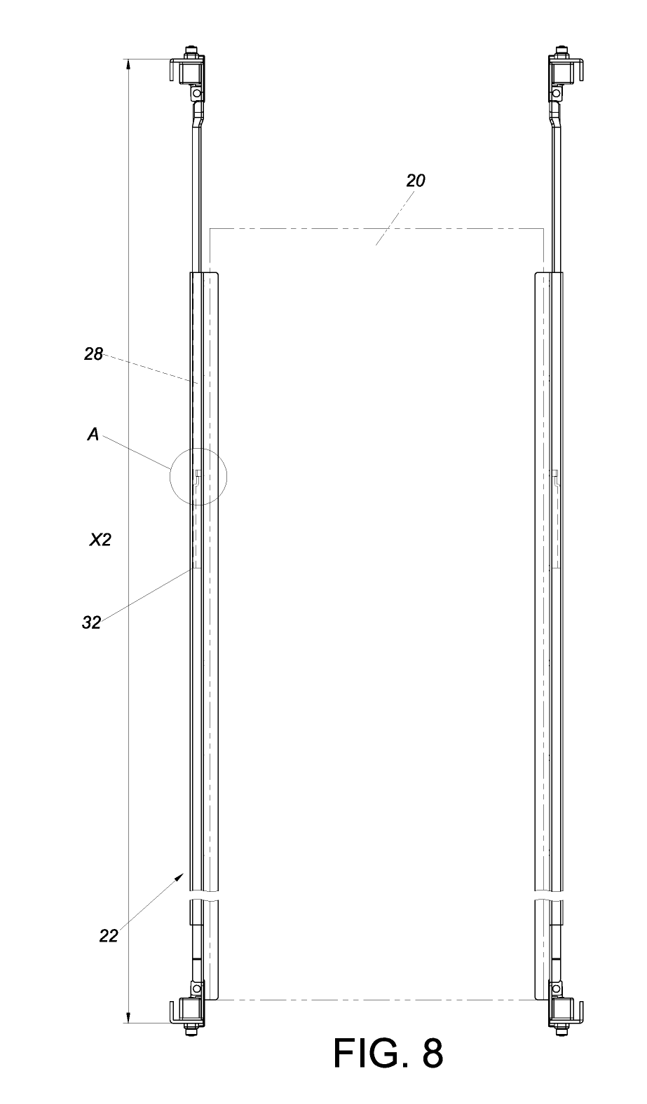

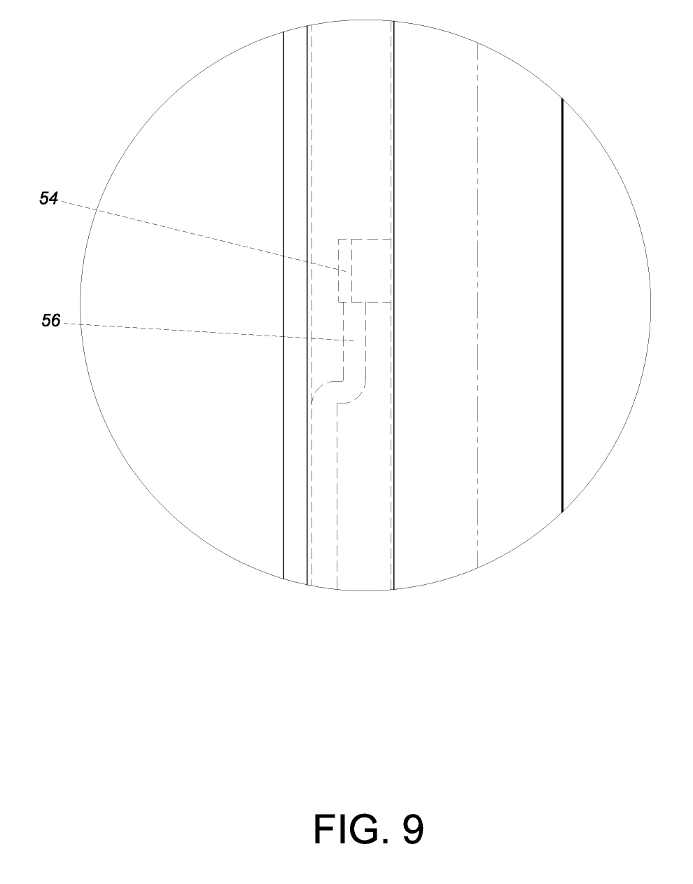

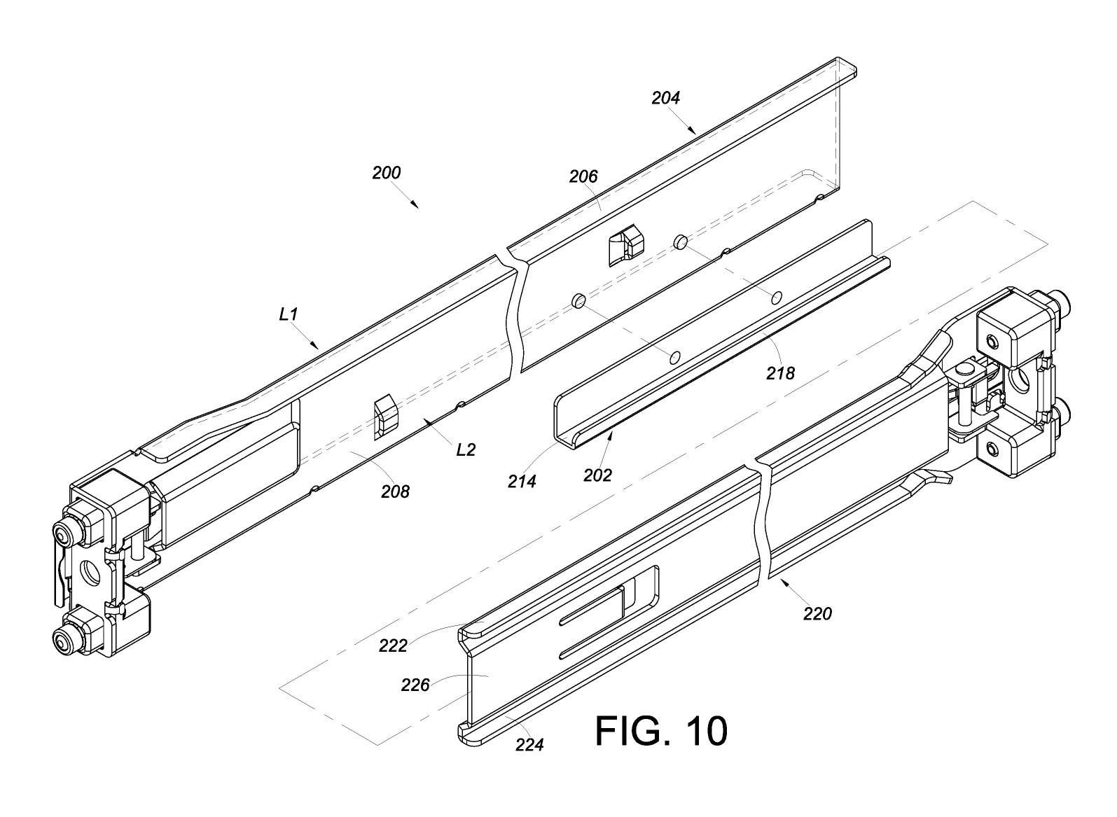

Referring to FIG. 5 to FIG. 7, the first feature 54 and the second feature 56 do not contact each other when the first bracket 28 and the second bracket 32 are extended to a first length X1. The second bracket 32 in this state can be moved with respect to the first bracket 28 through the supporting channel 46 as shown in FIG. 8 and FIG. 9. Once the first bracket 28 and the second bracket 32 are extended to a second length X2, the first feature 54 and the second feature 56 contact each other, thereby setting a limit to the adjustment (i.e., relative displacement) of the first bracket 28 and the second bracket 32 for the sake of safety.

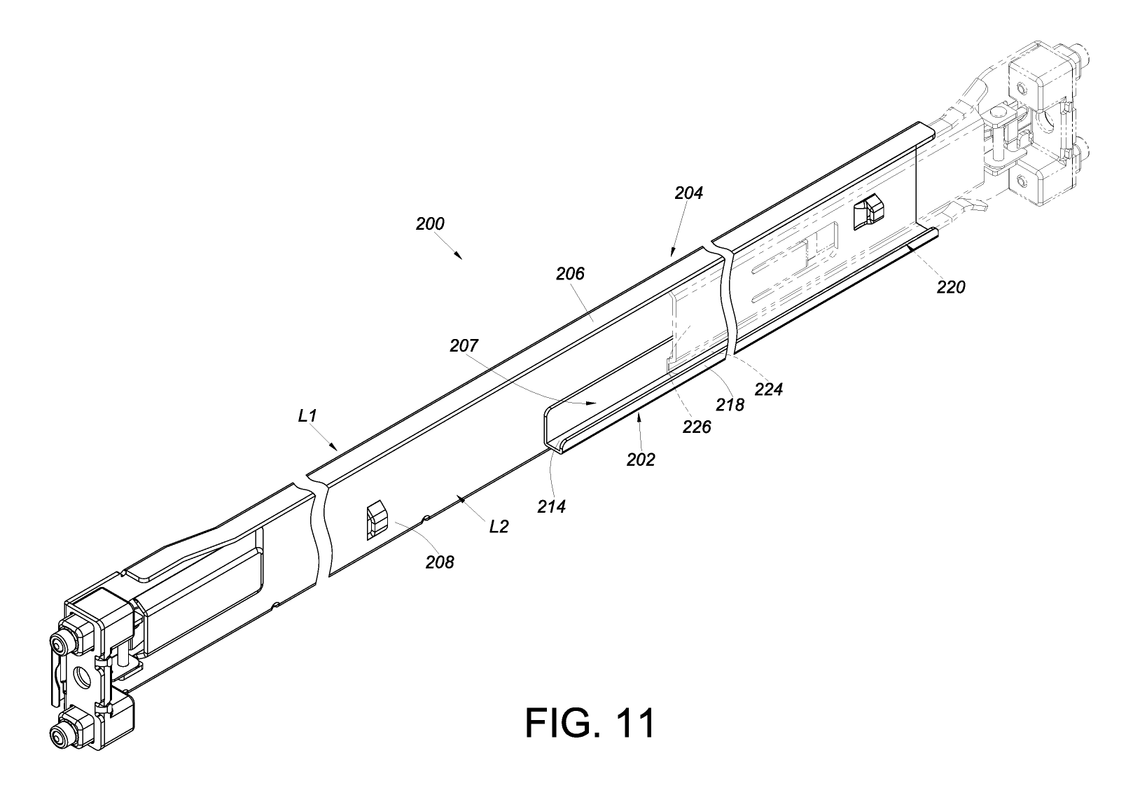

FIG. 10 to FIG. 12 show a supporting assembly 200 according to the second embodiment of the present invention. The supporting assembly 200 is different from the supporting assembly 22 of the first embodiment substantially in that the supporting frame 202 is a separate component connected to the first bracket 204. For example, the supporting frame 202 may be fixedly connected to the first bracket 204 by riveting or soldering, or the supporting frame 202 may be detachably connected to the first bracket 204 through mechanical engagement or by a threaded means.

The first bracket 204 has a second supporting section 206 while the supporting frame 202 has a first supporting section 214. The first supporting section 214 and the second supporting section 206 jointly constitute a supporting channel 207 for supporting the sidewall 226 of the second bracket 220.

The first bracket 204 includes a sidewall 208, and the sidewall 208 has a first lateral side L1 and a second lateral side L2.

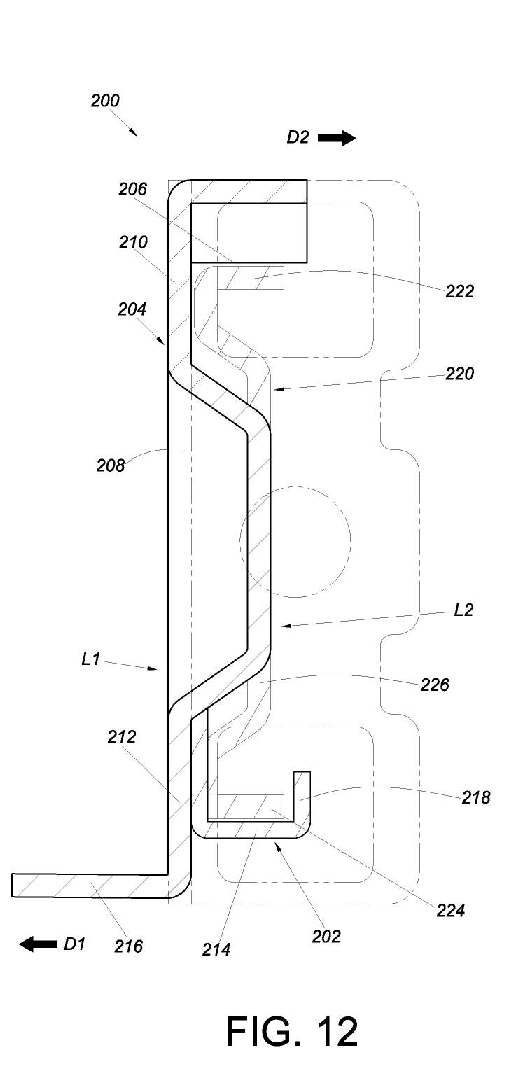

As shown in FIG. 12, the sidewall 208 of the first bracket 204 has an upper portion 210 and a lower portion 212, and the first supporting section 214 and the second supporting section 206 are located on the second lateral side L2. The first supporting section 214 is adjacent to the lower portion 212 while the second supporting section 206 is adjacent to the upper portion 210. A carrying portion 216 is arranged on the first lateral side L1 and extends in a first direction D1. The first supporting section 214 and the second supporting section 206 extend in a second direction D2. The first supporting section 214 is connected with a first bent section 218. Here, the first bent section 218 is substantially perpendicularly connected to the first supporting section 214 by way of example. The second bracket 220 includes an upper wall 222 and a lower wall 224 in addition to the sidewall 226, which is connected between the upper wall 222 and the lower wall 224. The lower wall 224 corresponds in position to the first supporting section 214 while the upper wall 222 corresponds in position to the second supporting section 206.

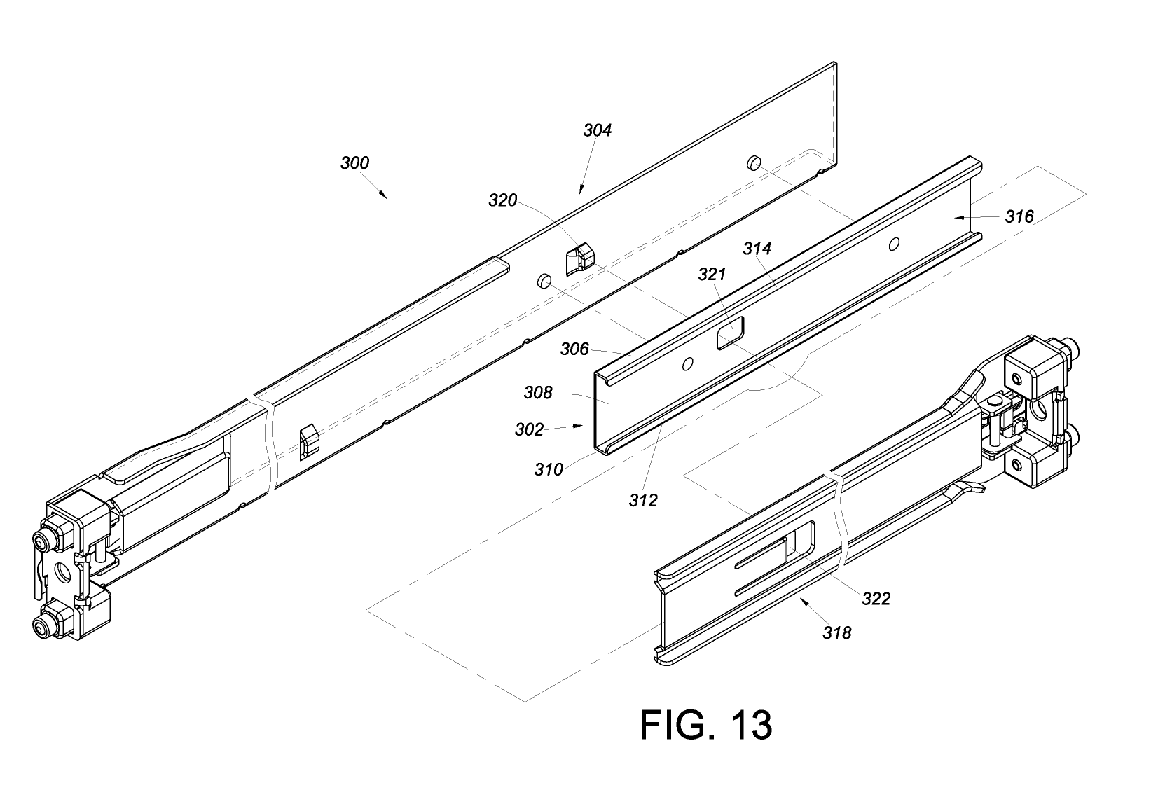

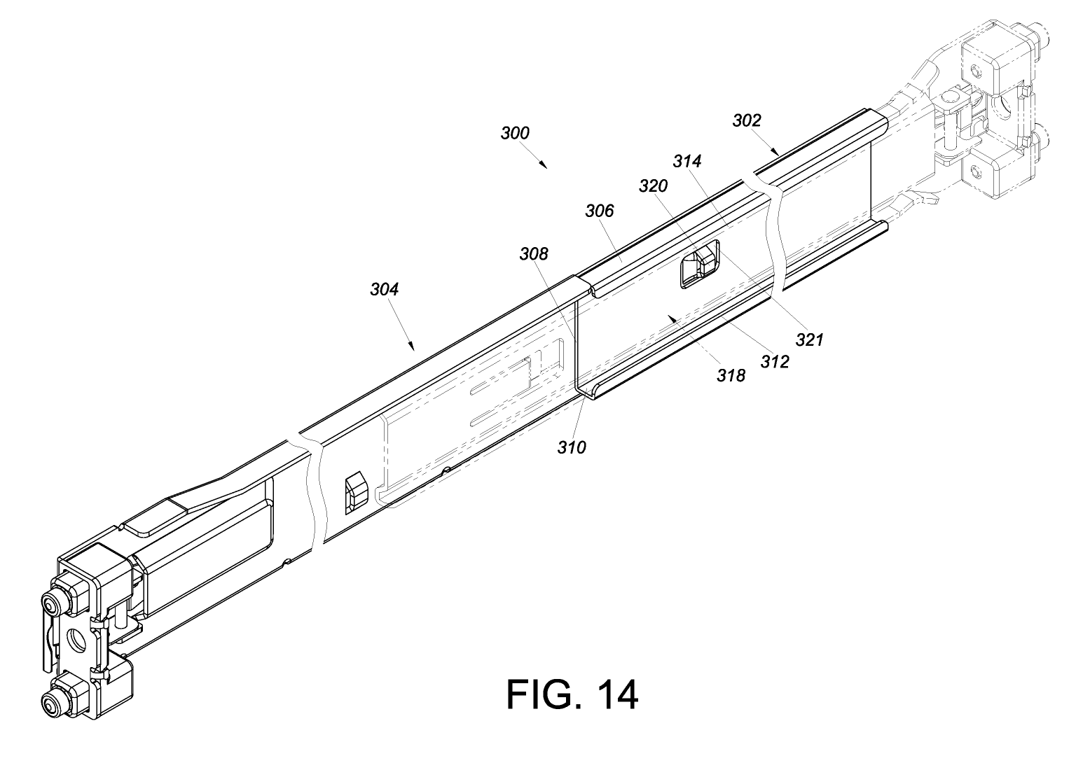

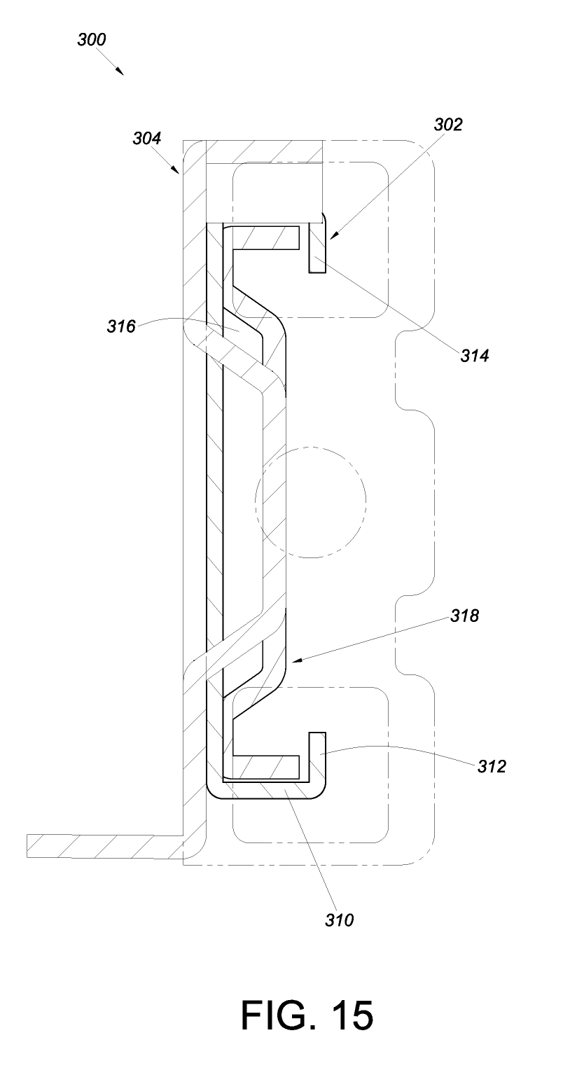

FIG. 13 to FIG. 15 show a supporting assembly 300 according to the third embodiment of the present invention. The supporting assembly 300 is different from the supporting assembly 22 of the first embodiment substantially in that the supporting frame 302 is a separate component connected to the first bracket 304. For example, the supporting frame 302 may be fixedly connected to the first bracket 304 by riveting or soldering, or the supporting frame 302 may be detachably connected to the first bracket 304 through mechanical engagement or by a threaded means.

The supporting frame 302 has a second supporting section 306 as well as a first supporting section 310. The supporting frame 302 further has an intermediate wall 308 connected between the first supporting section 310 and the second supporting section 306. The first supporting section 310 is connected with a first bent section 312, and the second supporting section 306 is connected with a second bent section 314.

The first supporting section 310, the second supporting section 306, and the intermediate wall 308 define a supporting channel 316 for supporting the second bracket 318.

The intermediate wall 308 of the supporting frame 302 is formed with a hole 321 in order not to interfere with the first feature 320 of the first bracket 304. The first feature 320 of the first bracket 304 extends through the hole 321 in the intermediate wall 308 of the supporting frame 302 to work with the second feature 322 of the second bracket 318. The structural configurations and functions of the first feature 320 and of the second feature 322 are the same as those of their counterparts in the first embodiment and therefore will not be repeated.

According to the above, the supporting assemblies disclosed herein preferably have the following features:
1. The supporting frame and the first bracket of each supporting assembly may be integrally formed, or the supporting frame may be a separate component connected to the first bracket; in either case, the supporting frame serves to increase the structural strength of the supporting assembly. Moreover, the supporting frame of the third as well as the second embodiment may be detachably connected to the first bracket to facilitate assembly.
2. The supporting assemblies can be adjusted in length to adapt to racks of different depths.
3. The supporting assemblies are configured to be mounted on a rack to directly support the object they carry.

While the present invention has been disclosed through the embodiments described above, it should be understood that the embodiments are not intended to be restrictive of the scope of the invention. The scope of patent protection sought by the applicant is defined by the appended claims.

What is claimed is:

1. A supporting assembly, comprising:
a first bracket including a first end portion and a second end portion;
a supporting frame connected to the first bracket at a position adjacent to the second end portion of the first bracket, wherein the supporting frame has a first supporting section; and
a second bracket;
wherein one of the first bracket and the supporting frame is provided with a second supporting section, and the first supporting section and the second supporting section jointly constitute a supporting channel for supporting the second bracket.

2. The supporting assembly of claim 1, wherein the second bracket is mounted to the first bracket through the supporting channel, the first bracket and the second bracket includes a first mounting member and a second mounting member respectively, and the second mounting member is away from the first mounting member.

3. The supporting assembly of claim 1, wherein the first bracket has a first lateral side and a second lateral side, the first lateral side is provided with a carrying portion, and the first supporting section is located on the second lateral side.

4. The supporting assembly of claim 3, wherein the second supporting section is located on the second lateral side.

5. The supporting assembly of claim 1, wherein the first bracket has a first feature, the second bracket has a second feature, the first feature and the second feature do not contact each other when the first bracket and the second bracket are extended to a first length, and the first feature and the second feature contact each other when the first bracket and the second bracket are extended to a second length.

6. The supporting assembly of claim 5, wherein the first feature is one of a protruding portion and an elastic arm, and the second feature is the other of the protruding portion and the elastic arm.

7. The supporting assembly of claim 4, wherein the supporting frame is integrally formed with the first bracket.

8. The supporting assembly of claim 7, wherein the first bracket has the second supporting section.

9. The supporting assembly of claim 8, wherein the first bracket includes a sidewall, the sidewall has the first lateral side and the second lateral side, the sidewall further has an upper portion and a lower portion, the first supporting section is adjacent to the lower portion, and the second supporting section is adjacent to the upper portion.

10. The supporting assembly of claim 9, wherein the first supporting section is connected with a first bent section, and the second supporting section is connected with a second bent section.

11. The supporting assembly of claim 10, wherein the second bracket includes an upper wall, a lower wall, and a sidewall connected between the upper wall and the lower wall; the lower wall corresponds in position to the first supporting section; and the upper wall corresponds in position to the second supporting section.

12. The supporting assembly of claim 3, wherein the supporting frame is a separate component connected to the first bracket.

13. The supporting assembly of claim 12, wherein the first bracket has the second supporting section.

14. The supporting assembly of claim 13, wherein the first bracket includes a sidewall, the sidewall has the first lateral side and the second lateral side, the sidewall further has an upper portion and a lower portion, the first supporting section is adjacent to the lower portion, and the second supporting section is adjacent to the upper portion.

15. The supporting assembly of claim 13, wherein the first supporting section is connected with a first bent section.

16. The supporting assembly of claim 15, wherein the second bracket includes an upper wall, a lower wall, and a sidewall connected between the upper wall and the lower wall; the lower wall corresponds in position to the first supporting section; and the upper wall corresponds in position to the second supporting section.

17. The supporting assembly of claim 4, wherein the supporting frame is a separate component connected to the first bracket, the supporting frame has the second supporting section and an intermediate wall connected between the first supporting section and the second supporting section, the first supporting section is connected with a first bent section, and the second supporting section is connected with a second bent section.

18. A supporting assembly adapted to be mounted on a rack, the supporting assembly comprising:
a first bracket including a sidewall, wherein the sidewall of the first bracket includes a first end portion and a second end portion, there is a first mounting member arranged adjacent to the first end portion, and the sidewall of the first bracket has a first lateral side and a second lateral side;
a supporting frame connected to the second lateral side, wherein the supporting frame has a first supporting section; and
a second bracket including a sidewall and a second mounting member;
wherein one of the first bracket and the supporting frame is provided with a second supporting section, and the first supporting section and the second supporting section jointly constitute a supporting channel for supporting the sidewall of the second bracket;
wherein the first bracket is mounted at a first position on a first side of the rack through the first mounting member, and the second bracket is mounted at a second position on the first side of the rack through the second mounting member.

19. The supporting assembly of claim 18, wherein the sidewall of the first bracket has a carrying portion on the first lateral side in order for the supporting assembly to carry an external object through the carrying portion.

20. The supporting assembly of claim 18, wherein the supporting frame is adjacent to the second end portion of the first bracket, and the supporting frame is integrally formed with the first bracket or is a separate component connected to the first bracket.
